(19) United States
(12) Patent Application Publication
(10) Pub. No.: US 2023/0107182 A1
(43) Pub. Date: Apr. 6, 2023

(54) Bottom Air Spacer by Oxidation

(71) Applicant: International Business Machines Corporation, Armonk, NY (US)

(72) Inventors: HUIMEI ZHOU, Albany, NY (US); Yi Song, Albany, NY (US); Veeraraghavan S. Basker, Schenectady, NY (US); Curtis S. Durfee, Schenectady, NY (US); Shahab Siddiqui, Clifton Park, NY (US)

(21) Appl. No.: 17/494,061

(22) Filed: Oct. 5, 2021

(51) Int. Cl. H01L 29/66; H01L 29/417; H01L 29/78; H01L 29/786

(52) U.S. Cl. CPC H01L 29/66666; H01L 29/785; H01L 29/7827; H01L 29/41791; H01L 29/66795; H01L 29/78642

(57) ABSTRACT

VFET devices having a porous bottom air spacer formed by oxidation are provided. In one aspect, a VFET device includes: at least one fin present on a substrate, wherein the at least one fin serves as a vertical fin channel of the VFET device; a bottom source/drain region at a base of the at least one fin; a bottom air-containing spacer disposed on the bottom source/drain region; a gate stack alongside the at least one fin; a top spacer above the gate stack at a top of the at least one fin; and a top source/drain region at a top of the at least one fin. A method of forming a VFET device is also provided.

### FIELD OF THE INVENTION

The present invention relates to vertical field-effect transistor (VFET) devices, and more particularly, to VFET devices having a porous bottom air spacer and techniques for fabrication thereof using an oxidation process.

### BACKGROUND OF THE INVENTION

As opposed to planar complementary metal-oxide-semiconductor (CMOS) devices, vertical field effect transistor (VFET) devices are oriented with a vertical fin channel disposed on a bottom source/drain and a top source/drain disposed on the fin channel. VFET devices are being pursued as a viable device option for continued CMOS scaling.

There are, however, some notable challenges associated with implementing a VFET design. For instance, with the vertically-oriented configuration of a VFET, there is often a large area of overlap area between the gate stack and the bottom source/drain region. This large area of overlap can undesirably lead to a significant amount of parasitic capacitance between the gate stack and the bottom source/drain region.

Parasitic capacitance refers to the capacitance that exists between device components in close proximity to one another (in this case the gate stack and the bottom source/drain region) which results in a stored electric charge. Such parasitic capacitance can negatively impact VFET device performance.

Therefore, techniques for efficiently and effectively reducing parasitic capacitance in VFET devices would be desirable.

### SUMMARY OF THE INVENTION

The present invention provides vertical field-effect transistor (VFET) devices having a porous bottom air spacer formed by oxidation. In one aspect of the invention, a VFET device is provided. The VFET device includes: at least one fin present on a substrate, wherein the at least one fin serves as a vertical fin channel of the VFET device; a bottom source/drain region at a base of the at least one fin; a bottom air-containing spacer disposed on the bottom source/drain region; a gate stack alongside the at least one fin; a top spacer above the gate stack at a top of the at least one fin; and a top source/drain region at a top of the at least one fin.

In another aspect of the invention, another VFET device is provided. The VFET device includes: at least one fin present on a substrate, wherein the at least one fin serves as a vertical fin channel of the VFET device; a bottom source/drain region at a base of the at least one fin, wherein the bottom source/drain region is in direct contact with a first portion of a sidewall of the at least one fin; a bottom air-containing spacer disposed directly on the bottom source/drain region, wherein the bottom air-containing spacer is in direct contact with a second portion of the sidewall of the at least one fin; a gate stack alongside the at least one fin; a top spacer above the gate stack at a top of the at least one fin; and a top source/drain region at a top of the at least one fin.

In yet another aspect of the invention, a method of forming a VFET device is provided. The method includes: patterning at least one fin in a substrate; forming a bottom source/drain region at a base of the at least one fin; forming a bottom air spacer on the bottom source/drain region using oxidation, wherein the bottom air spacer includes air-containing pores distributed throughout the bottom spacer; forming a gate stack alongside the at least one fin, wherein the at least one fin serves as a vertical fin channel of the VFET device; forming a top spacer above the gate stack at a top of the at least one fin; and forming a top source/drain region at a top of the at least one fin. For instance, a bottom spacer can be formed on the bottom source/drain region, wherein the bottom spacer includes silicon germanium (SiGe) having from about 50% Ge to about 100% Ge; and the bottom spacer can be annealed in an oxygen ambient to form the bottom air spacer on the bottom source/drain region.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a plurality of fins having been patterned in a substrate using fin hardmasks, and a first sidewall spacer having been formed alongside the fins according to an embodiment of the present invention;

FIG. 2 is a cross-sectional diagram illustrating an etch having been performed to recess the substrate in between the fins thereby extending the base of the fins below the first sidewall spacer according to an embodiment of the present invention;

FIG. 3 is a cross-sectional diagram illustrating a lateral etch of the exposed base of the fins having been performed to trim/reduce the width of the bottom of the fins according to an embodiment of the present invention;

FIG. 4 is a cross-sectional diagram illustrating a second sidewall spacer having been formed alongside the fins over the first sidewall spacer creating a bilayer spacer according to an embodiment of the present invention;

FIG. 5 is a cross-sectional diagram illustrating an etch having been performed to further recess the substrate in between the fins thereby extending the base of the fins below the bilayer spacer according to an embodiment of the present invention;

FIG. 6 is a cross-sectional diagram illustrating an optional lateral etch of the exposed base of the fins below the bilayer spacer having been performed to trim/reduce the width of the bottom of the fins according to an embodiment of the present invention;

FIG. 7 is a cross-sectional diagram illustrating bottom source/drain regions having been formed at the base of the fins beneath the bilayer spacer according to an embodiment of the present invention;

FIG. 8 is a cross-sectional diagram illustrating the second sidewall spacer having been removed from the fins selective to the first sidewall spacer according to an embodiment of the present invention;

FIG. 9 is a cross-sectional diagram illustrating a high germanium (Ge) content bottom spacer having been formed on the bottom source/drain regions at the base of the fins beneath the first sidewall spacer according to an embodiment of the present invention;

FIG. 10 is a cross-sectional diagram illustrating the first sidewall spacer having been removed, gate stacks (including a gate dielectric and at least one workfunction-setting metal) having been formed alongside the fins and over the bottom source/drain regions and bottom spacer, and an encapsulation liner having been formed on the gate stacks over the fins according to an embodiment of the present invention;

FIG. 11 is a cross-sectional diagram illustrating the bottom spacer having been oxidized to form a bottom air-containing spacer between the bottom source/drain regions and the gate stacks according to an embodiment of the present invention;

FIG. 12 is a cross-sectional diagram illustrating a (first) interlayer dielectric (ILD) having been deposited over the gate stacks and fins according to an embodiment of the present invention;

FIG. 13 is a cross-sectional diagram illustrating the encapsulation liner, the workfunction-setting metal(s), the gate dielectric, and the fin hardmasks have been removed from the top of the fins (i.e., the vertical fin channels of the VFET device) creating gaps between the sidewall at the tops of the fins and the first ILD according to an embodiment of the present invention;

FIG. 14 is a cross-sectional diagram illustrating a top spacer having been formed above the gate stack in the gaps alongside the tops of the fins (i.e., vertical fin channels) according to an embodiment of the present invention;

FIG. 15 is a cross-sectional diagram illustrating top source/drain regions having been formed in the trenches at the tops of the fins (i.e., vertical fin channels) according to an embodiment of the present invention;

FIG. 16 is a cross-sectional diagram illustrating a (second) ILD having been deposited onto the first ILD over the fins, and contact trenches having been patterned in the second ILD over each of the top source/drain regions according to an embodiment of the present invention;

FIG. 17 is a cross-sectional diagram illustrating the contact trenches having been filled with a metal(s) to form contacts to the top source/drain regions according to an embodiment of the present invention;

FIG. 18 is a cross-sectional diagram which follows from FIG. 9 illustrating, according to an alternative embodiment, a capping layer having been formed on the bottom spacer according to an embodiment of the present invention;

FIG. 19 is a cross-sectional diagram illustrating the bottom spacer having been oxidized to form a bottom air-containing spacer between the bottom source/drain regions and the capping layer according to an embodiment of the present invention;

FIG. 20 is a cross-sectional diagram illustrating the capping layer having been selectively removed according to an embodiment of the present invention; and

FIG. 21 is a cross-sectional diagram illustrating the first sidewall spacer having been removed and the gate stacks (including the gate dielectric and the workfunction-setting metal(s)) having been formed alongside the fins and over the bottom source/drain regions and bottom air-containing spacer with the remainder of the process being the same as in FIGS. 12-17 above according to an embodiment of the present invention.

### DETAILED DESCRIPTION OF PREFERRED EMBODIMENTS

As provided above, with a vertical field effect transistor (VFET) device architecture there is a considerable area of overlap between the gate stack and the bottom source/drain region. This overlap can undesirably lead to high parasitic capacitance which negatively impacts the device performance.

A bottom spacer is often employed to offset the gate stack from the bottom source/drain region. Conventional designs typically employ an oxide or nitride dielectric material such as silicon nitride (SiN) for forming the bottom spacer. Even so, the effect of parasitic capacitance on the device performance remains significant.

On the other hand, air has a significantly lower dielectric constant than these conventional oxide and nitride dielectric spacer materials. For instance, by way of example only, at room temperature (i.e., 25° C. (°C)), air has a dielectric constant of 1.00059, whereas SiN has a dielectric constant of about 9.5. Thus, being able to effectively implement a bottom air spacer in a VFET device design would greatly reduce the parasitic capacitance.

Advantageously, provided herein are techniques for forming a porous bottom air spacer for a VFET device using an oxidation process. As will be described in detail below, the bottom spacers are formed from a semiconductor material such as silicon germanium (SiGe) having a high germanium (Ge) content (also referred to herein as ‘high Ge content SiGe’). The high Ge content SiGe is then oxidized to form a porous oxide (e.g., silicon oxide (SiOx)) bottom air spacer between the gate stack and the bottom source/drain region. By ‘porous’ it is meant that there are air-containing pores formed (by way of the present process) throughout the bottom spacer.

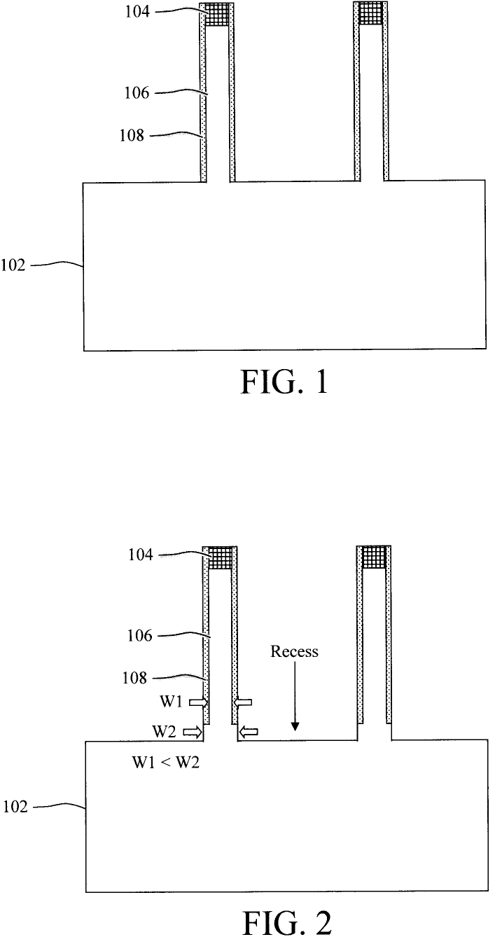

Given the above overview, an exemplary methodology for fabricating a VFET device is now described by way of reference to FIGS. 1-17. As shown in FIG. 1, the process begins with the patterning of a plurality of fins 106 in a substrate 102. According to an exemplary embodiment, substrate 102 is a bulk semiconductor wafer, such as a bulk silicon (Si), bulk germanium (Ge), bulk silicon germanium (SiGe) and/or bulk III-V semiconductor wafer. Alternatively, substrate 102 can be a semiconductor-on-insulator (SOI) wafer. A SOI wafer includes a SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, substrate 102 may already have pre-built structures (not shown) such as transistors, diodes, capacitors, resistors, interconnects, wiring, etc.

Standard lithography and etching techniques can be employed to pattern the fins 106 in substrate 102. For instance, with standard lithography and etching techniques, a lithographic stack (not shown), e.g., photoresist/organic planarizing layer (OPL)/anti-reflective coating (ARC), is used to pattern fin hardmasks 104 with the footprint and location of each of the fins 106. Suitable hardmask materials include, but are not limited to, nitride hardmask materials such as silicon nitride (SiN), silicon oxynitride (SiON) and/or silicon carbide nitride (SiCN). A directional (i.e., anisotropic) etching process such as reactive ion etching (RIE) is then employed to transfer the pattern from the fin hardmask 104 to the substrate 102, forming fins 106 in the substrate 102. Alternatively, the fin hardmasks 104 can be formed by other suitable techniques, including but not limited to, sidewall image transfer (SIT), self-aligned double patterning (SADP), self-aligned quadruple patterning (SAQP), and other self-aligned multiple patterning (SAMP). As shown in FIG. 1, the as-patterned fins 106 extend partway through the substrate 102.

As will be described in detail below, the bottom source/drain regions will be grown at a base of the fins 106, followed by the bottom spacers (with later oxidation to form the porous bottom air spacer). To do so, a unique bilayer spacer-based process is employed whereby a first sidewall spacer is formed alongside the fins 106, followed by an etch to extend the base of the fins 106 below the first sidewall spacer. A second sidewall spacer is then formed over the first sidewall spacer (i.e., forming the bilayer spacer), followed by another etch to further extend the base of the fins 106 below the second sidewall spacer.

The bilayer spacer is then used to place the bottom source/drain region at the base of the fins 106. After which, the second sidewall spacer is removed and the first sidewall spacer is used to place the bottom spacer over the bottom source/drain region at the base of the fins 106. The first sidewall spacer is then also removed.

Namely, as shown in FIG. 1, a first sidewall spacer 108 is formed alongside the fins 106. By way of example only, the first sidewall spacer 108 can be formed by depositing a layer of a spacer material onto the fins 106 and exposed surfaces of the substrate 102. A directional (i.e., anisotropic) etching process such as RIE can then be used to remove the material deposited onto horizontal surfaces. What remains is the spacer material on the sidewalls of the fins 106 that serves as the first sidewall spacer 108.

Suitable materials for the first sidewall spacer 108 include, but are not limited to, SiN, silicon carbide (SiC), silicon borocarbonitride (SiBCN) and/or silicon oxycarbonitride (SiOCN) which can be deposited using a process such as chemical vapor deposition (CVD), atomic layer deposition (ALD), or physical vapor deposition (PVD). According to an exemplary embodiment, the first sidewall spacer 108 is formed having a thickness of from about 2 nanometers (nm) to about 5 nm and ranges therebetween.

With the first sidewall spacer 108 now protecting the sidewalls of the fins 106, as highlighted above, an etch is then performed to recess the substrate 102 in between the fins 106 thereby extending the base of the fins 106 below the first sidewall spacer 108. See FIG. 2. A directional (i.e., anisotropic) etching process such as RIE can be employed for this recess etch.

As shown in FIG. 2, the first sidewall spacer 108 covers a portion of the underlying substrate during this recess etch. As a result, the bottom of the fins 106 is now wider than the portions of the fins 106 adjacent to the first sidewall spacer 108. Namely, the portions of the fins 106 adjacent to the first sidewall spacer 108 have a width W1 and the bottom of the fins 106 have a width W2, whereby W1 is less than W2, i.e., W1 < W2. However, as will be described in detail below, the bottom of the fins 106 is next trimmed to reduce its width. Trimming the width at the bottom of the fins has notable advantages such as, among other things, reducing a distance between the bottom source/drain regions and the vertical fin channel (see below).

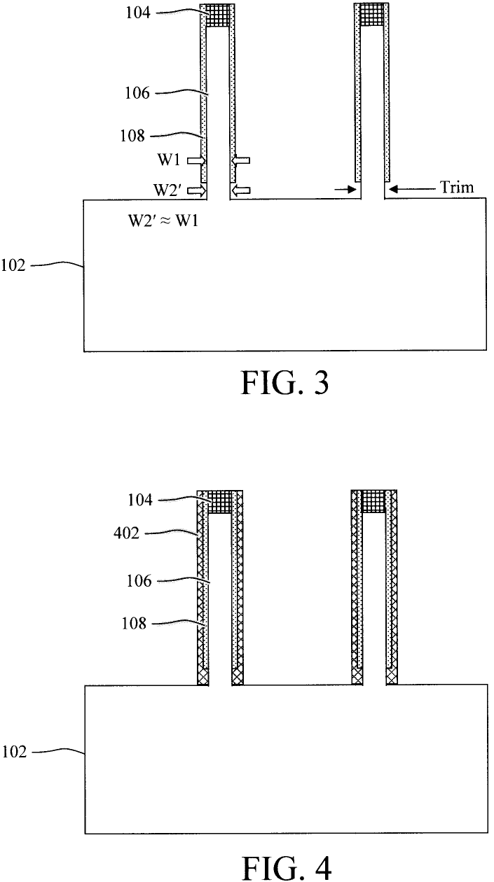

Namely, a lateral etch of the exposed base of the fins 106 is next performed to trim/reduce the width of the bottom of the fins 106 from W2 to W2'. See FIG. 3. According to an exemplary embodiment, the reduced width W2' is approximately the same as the width W1 of the fins 106 adjacent to the first sidewall spacer 108, i.e., W2' ≈ W1. For instance, W2' differs from W1 by less than or equal to about 0.25 nm. A non-directional (i.e., isotropic) etching process such as a wet chemical etch or a gas phase etch can be employed to trim the base of the fins 106 below the first sidewall spacer 108.

As highlighted above, a second sidewall spacer 402 is next formed alongside the fins 106 over the first sidewall spacer 108. See FIG. 4. This combination of first sidewall spacer 108 and second sidewall spacer 402 is what is being referred to herein as a bilayer spacer. Like first sidewall spacer 108, the second sidewall spacer 402 can be formed by depositing a layer of a spacer material onto the fins 106 and exposed surfaces of the substrate 102 over the first sidewall spacer 108. A directional (i.e., anisotropic) etching process such as RIE can then be used to remove the material deposited onto horizontal surfaces. What remains is the spacer material on the first sidewall spacer 108 along the sidewalls of the fins 106 that serves as the second sidewall spacer 402.

The materials chosen for the first/second sidewall spacers 108 and 402 need to enable the selective removal of the second sidewall spacers 402 relative to the first sidewall spacers 108. Namely, as will be described in detail below, this will enable the formation of the bottom spacers on the bottom source/drain regions at the base of the fins 106. By way of example only, suitable materials for the second sidewall spacer 402 include, but are not limited to, silicon nitride (SiN) which can be deposited using a process such as CVD, ALD, or PVD. According to an exemplary embodiment, the second sidewall spacer 402 is formed having a thickness of from about 2 nm to about 8 nm and ranges therebetween.

Notably, as shown in FIG. 4, the second sidewall spacer 402 covers the first sidewall spacer 108 as well as the sidewall of the base of the fins 106 below the first sidewall spacer 108. Namely, the second sidewall spacer 402 is in direct contact with the fins 106 below the first sidewall spacer 108. As will be described in detail below, this placement of the second sidewall spacer 402 along the fins 106 below the first sidewall spacer 108, will first enable the formation of the bottom source/drain regions, followed by the bottom spacer.

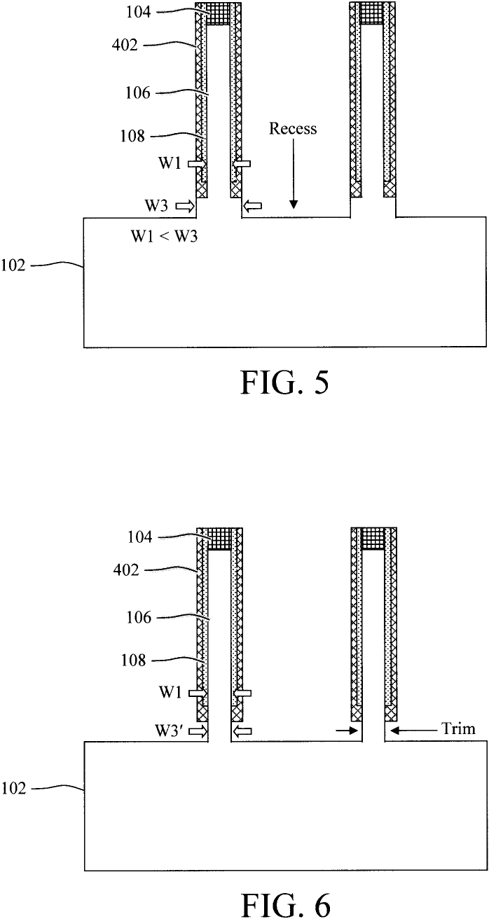

Next, in the same manner as described above, the substrate is again recessed to extend the base of the fins 106 below the bilayer spacer (i.e., first sidewall spacer 108/second sidewall spacer 402) followed by a lateral trimming of the exposed base of the fins 106. Namely, with the first sidewall spacer 108 and the second sidewall spacer 402 protecting the sidewalls of the fins 106, an etch is performed to further recess the substrate 102 in between the fins 106 thereby extending the base of the fins 106 below the bilayer spacer. See FIG. 5. A directional (i.e., anisotropic) etching process such as RIE can be employed for this recess etch.

As shown in FIG. 5, the bilayer spacer (i.e., first sidewall spacer 108/second sidewall spacer 402) covers a portion of the underlying substrate during this recess etch. As a result, the bottom of the fins 106 is now wider than the portions of the fins 106 adjacent to the bilayer spacer. Namely, the portions of the fins 106 adjacent to the bilayer spacer have the same width W1 as described above, and the bottom of the fins 106 have a width W3, whereby W1 is less than W2, i.e., W1 < W2. Based on the combined thickness of the first sidewall spacer 108 and second sidewall spacer 402, the width W3 at the bottom of the fins 106 is also greater than the width W2 resulting from the first recess etch (see FIG. 2 - described above), i.e., W2 < W3. An optional trim at the bottom of the fins 106 can next be performed to reduce its width. It is notable that, while trimming the exposed base of the fins 106 below the bilayer spacer can help improve resistance at the bottom source/drain region, doing so is not required, and embodiments are contemplated herein where trimming of the fins 106 below the bilayer spacer is not performed.

However, in the exemplary embodiment shown illustrated in FIG. 6, a lateral etch of the exposed base of the fins 106 below the bilayer spacer is performed to trim/reduce the width of the bottom of the fins 106 from W3 to W3'. According to an exemplary embodiment, the reduced width W3' is approximately the same as the width W1 of the fins 106 adjacent to the bilayer spacer, i.e., W3' ≈ W1. For instance, W3' differs from W1 by less than or equal to about 0.25 nm. A non-directional (i.e., isotropic) etching process such as a wet chemical etch or a gas phase etch can be employed to trim the base of the fins 106 below the bilayer spacer.

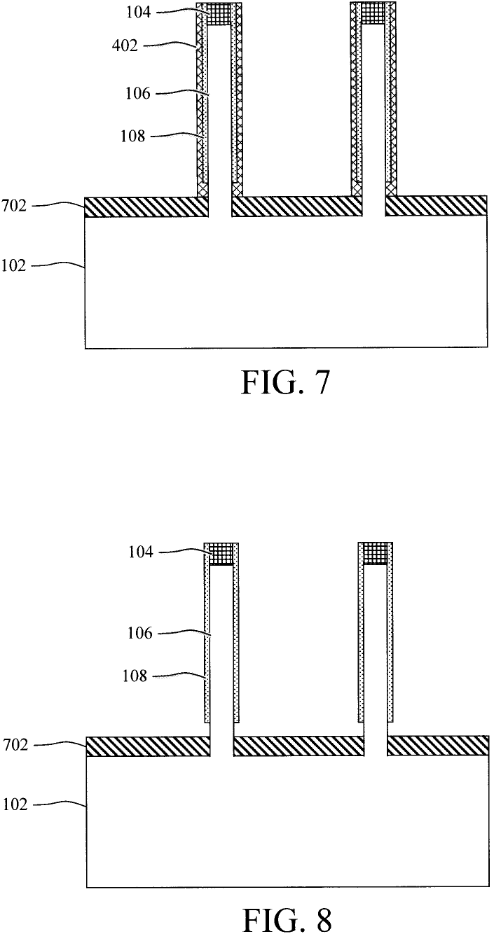

Bottom source/drain regions 702 are then formed at the base of the fins 106 beneath the bilayer spacer (i.e., first sidewall spacer 108/second sidewall spacer 402). See FIG. 7. According to an exemplary embodiment, bottom source/drain regions 702 are formed from an in-situ doped (i.e., during growth) or ex-situ doped (e.g., via ion implantation) epitaxial material such as epitaxial Si, epitaxial SiGe, etc. grown at the base of the fins 106 and doped with an n-type or p-type dopant. Suitable n-type dopants include, but are not limited to, phosphorous (P) and/or arsenic (As). Suitable p-type dopants include, but are not limited to, boron (B). Growth of the bottom source/drain regions 702 is limited to the portion of the sidewall of the fins 106 beneath the bilayer spacer.

The second sidewall spacer 402 is then removed from the fins 106 selective to the first sidewall spacer 108. See FIG. 8. As shown in FIG. 8, the first sidewall spacer 108 remains in place covering the upper portions of the fins 106. However, removing the second sidewall spacer 402 exposes a portion of the sidewall at the base of the fins 106 above the bottom source/drain regions 702. As provided above, the second sidewall spacer 402 can be formed from a material such as SiN. In that case, an etch using a fluorine- and hydrogen-containing plasma can be employed to selectively remove the second sidewall spacer 402.

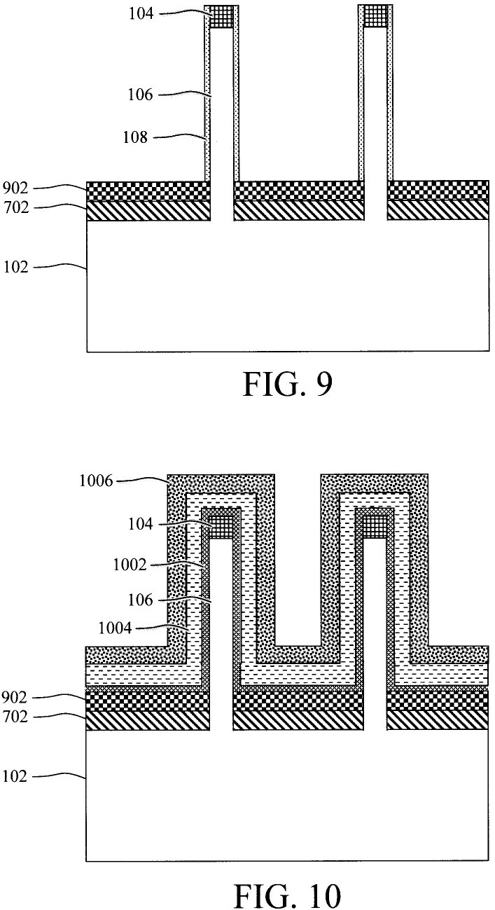

A bottom spacer 902 is then formed on the bottom source/drain regions 702 at the base of the fins 106 beneath the first sidewall spacer 108. See FIG. 9. According to an exemplary embodiment, the bottom spacer 902 is formed from a semiconductor material such as SiGe having a high Ge content (also referred to herein as ‘high Ge content SiGe’). By way of example only, the term ‘high Ge content SiGe’ as used herein refers to SiGe having from about 50% Ge to about 100% Ge (i.e., pure Ge) and ranges therebetween. For instance, in one non-limiting example, the bottom spacer 902 is formed from SiGe having greater than or equal to about 60% Ge, where in some cases the bottom spacer 902 is formed from SiGe having greater than or equal to about 75% Ge, and even further in some cases the bottom spacer 902 is formed from SiGe having greater than or equal to about 80% Ge. As highlighted above, the high Ge content SiGe will later be oxidized to form a porous oxide (e.g., SiOx) bottom air spacer over the bottom source/drain regions 702. Advantageously, the lower dielectric constant of the bottom air spacer helps to greatly reduce the parasitic capacitance.

In one embodiment, the bottom spacer 902 is formed from high Ge content SiGe epitaxial grown on the bottom source/drain regions 702 at the base of the fins 106. Epitaxial SiGe can be grown using Si and Ge precursors such as silane (SiH₄) or dichlorosilane and germane (GeH₄) or digermane (Ge₂H₆), respectively. The Ge content can be regulated by controlling the flow of the Ge precursor during growth. According to an exemplary embodiment, the bottom spacer 902 is formed having a thickness of from about 5 nm to about 20 nm and ranges therebetween. Growth of the bottom spacer 902 is limited to the portion of the sidewall of the fins 106 above the bottom source/drain regions 702 and beneath the first sidewall spacer 108.

Following formation of the bottom spacer 902, the first sidewall spacer 108 is removed. The particular etch chemistry employed to remove the first sidewall spacer 108 can be selected based on the material chosen for the first sidewall spacer 108. For instance, by way of example only, if the first sidewall spacer 108 is formed from SiN (see above), then a wet chemical etch with phosphoric acid (H₃PO₄) can be used to selectively remove the first sidewall spacer 108. Gate stacks are then formed alongside the fins 106 and over the bottom source/drain regions 702 and bottom spacer 902. See FIG. 10. As shown in FIG. 10, the gate stacks include a gate dielectric 1002 disposed on the fins 106 and at least one workfunction-setting metal 1004 disposed on the gate dielectric 1002. Although not explicitly shown in the figures, an interfacial oxide may be formed on the exposed surfaces of the fins 106 prior to the gate dielectric 1002 such that the gate dielectric 1002 is disposed on the fins 106 over the interfacial oxide. By way of example only, the interfacial oxide can be formed on the exposed surfaces of the fins 106 by a thermal oxidation, a chemical oxidation, or any other suitable oxide formation process. According to an exemplary embodiment, the interfacial oxide has a thickness of from about 0.5 nm to about 5 nm and ranges therebetween, e.g., about 1 nm.

Suitable materials for the gate dielectric 1002 include, but are not limited to, SiOx, SiN, silicon oxynitride (SiOxNy), high-κ materials, or any combination thereof. The term “high-κ” as used herein refers to a material having a relative dielectric constant κ which is much higher than that of silicon dioxide (e.g., a dielectric constant κ is about 25 for hafnium oxide (HfO₂) rather than 3.9 for SiO₂). Suitable high-κ materials include, but are not limited to, metal oxides such as HfO₂, hafnium silicon oxide (HfSiO), hafnium silicon oxynitride (HfSiO), lanthanum oxide (La₂O₃), lanthanum aluminum oxide (LaAlO₃), zirconium oxide (ZrO₂), zirconium silicon oxide (ZrSiO₄), zirconium silicon oxynitride (ZrSiOxNy), tantalum oxide (TaOx), titanium oxide (TiO), barium strontium titanium oxide (BaO₆SrTi₂), barium titanium oxide (BaTiO₃), strontium titanium oxide (SrTiO₃), yttrium oxide (Y₂O₃), aluminum oxide (Al₂O₃), lead scandium tantalum oxide (Pb(Sc,Ta)O₃) and/or lead zinc niobite (Pb(Zn,Nb)O). The high-κ material can further include dopants such as lanthanum (La), aluminum (Al) and/or magnesium (Mg). The gate dielectric 1002 can be deposited using a process or combination of processes such as, but not limited to, thermal oxidation, chemical oxidation, thermal nitridation, plasma oxidation, plasma nitridation, CVD, ALD, etc. According to an exemplary embodiment, the gate dielectric 1002 has a thickness of from about 1 nm to about 5 nm and ranges therebetween.

Suitable workfunction-setting metals 1004 include, but are not limited to, titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN), titanium carbide (TiC) titanium aluminum carbide (TiAlC), tantalum carbide (TaC) and/or hafnium carbide (HfC). The workfunction-setting metal(s) 1004 can be deposited using a process or combination of processes such as, but not limited to, CVD, ALD, PVD, sputtering, plating, evaporation, ion beam deposition, electron beam deposition, laser assisted deposition, chemical solution deposition, etc. According to an exemplary embodiment, the workfunction-setting metal(s) 1004 has a thickness of from about 5 nm to about 10 nm and ranges therebetween.

An encapsulation liner 1006 is then formed on the gate stacks (i.e., gate dielectric 1002 and workfunction-setting metal(s) 1004) over the fins 106. The encapsulation liner 1006 will serve to protect the gate stacks during subsequent processing steps. Suitable materials for the encapsulation liner 1006 include, but are not limited to, nitride materials such as SiN and/or silicon carbide nitride (SiCN) and/or amorphous silicon, which can be deposited using a process such as CVD, ALD or PVD. According to an exemplary embodiment, encapsulation liner 1006 has a thickness of from about 1 nm to about 5 nm and ranges therebetween.

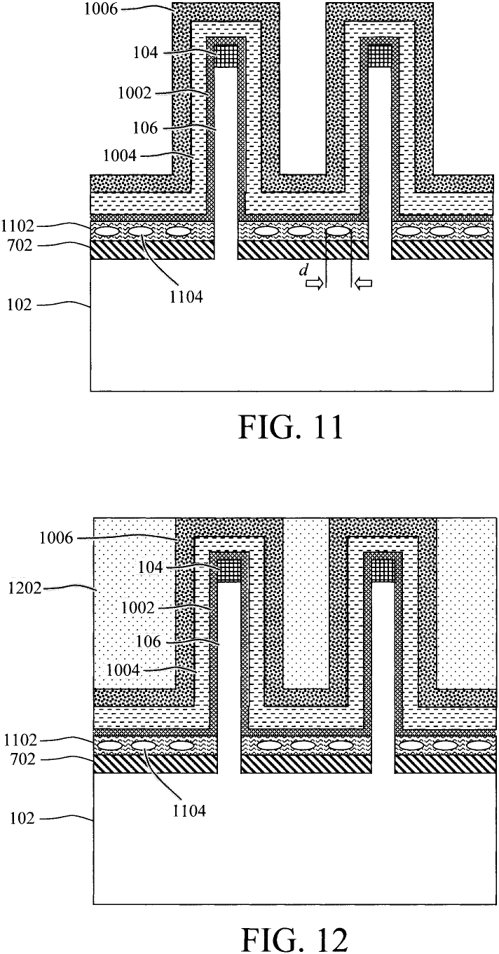

The bottom spacer 902 is then oxidized to form a bottom air-containing spacer 1102 between the bottom source/drain regions 702 and the gate stacks (i.e., gate dielectric 1002 and workfunction-setting metal(s) 1004). See FIG. 11. As provided above, the bottom spacer 902 is formed from high Ge content SiGe, i.e., SiGe having from about 50% Ge to about 100% Ge (i.e., pure Ge) and ranges therebetween, such as SiGe having greater than or equal to about 60% Ge, SiGe having greater than or equal to about 75% Ge, or even SiGe having greater than or equal to about 80% Ge. The presence of Ge in the bottom spacer 902 catalyzes the oxidation reaction, and an increase in temperature increases the reaction rate. See, for example, Mohamed A. Rabie et al., “A kinetic model for the oxidation of silicon germanium alloys,” Journal of Applied Physics, 98, 074904 (October 2005) (11 pages) (hereinafter “Rabie”). A higher Ge content also increases the reaction rate relative to, e.g., the underlying bottom source/drain regions 702. Thus, if the bottom source/drain regions 702 contain Ge (see above), it is preferable that the Ge content of the bottom spacer 902 is greater than the Ge content of the bottom source/drain regions 702. For instance, according to an exemplary embodiment, the bottom source/drain regions 702 contain from about 0% Ge to about 50% Ge and ranges therebetween. That way, the present techniques can be implemented to form the bottom air-containing spacer 1102 by oxidation with little if any oxidation also occurring in the bottom source/drain regions 702.

It was found herein that, by employing the present oxidation techniques, the resulting bottom air-containing spacer 1102 formed is pure SiOx meaning that there is no Ge present in the final bottom air-containing spacer 1102. Without being bound by any particular theory, it is believed that during this oxidation process, the Ge is sublimated as germanium oxide (GeO) which leaves behind pure SiOx as the bottom air-containing spacer 1102, with the vacancies in the material left by the Ge sublimation creating air-containing pores in the bottom air-containing spacer 1102. Namely, as shown in FIG. 11, bottom air-containing spacer 1102 has air-containing pores 1104 distributed throughout, these air-containing pores 1104 having a bubble shape. According to an exemplary embodiment, each of the air-containing pores 1104 has a size of from about 1 nm to about 15 nm and ranges therebetween, which is measured as the largest diameter d of each of the air-containing pores 1104 (see FIG. 11). The size of the air-containing pores 1104 formed can depend on factors such as the Ge content and/or thickness of the bottom spacer 902 (see above) and/or the temperature of the thermal oxidation anneal (see below). Namely, the higher the Ge content of the bottom spacer 902 and/or the greater the thickness of the bottom spacer 902 and/or the greater the temperature of the thermal oxidation anneal (within the limits provided herein), the greater the size of the resulting the air-containing pores 1104 will be. As described above, the presence of the air-containing pores 1104 in the bottom air-containing spacer 1102 helps to greatly reduce the parasitic capacitance between the gate stacks (i.e., gate dielectric 1002 and workfunction-setting metal(s) 1004) and the bottom source/drain regions 702. Thus, in one exemplary embodiment, the goal is to produce the largest (sized) air-containing pores 1104 possible in the bottom air-containing spacer 1102.

According to an exemplary embodiment, the bottom spacer 902 is oxidized using a thermal oxidation process whereby the VFET device structure is annealed in an oxygen (O₂)-containing ambient under conditions (e.g., temperature, duration, etc.) sufficient to form bottom air-containing spacer 1102 (i.e., pure SiOx) having air-containing pores 1104 distributed throughout. In one exemplary embodiment, the annealing is performed at a temperature of greater than about 700° C. (°C), for example, at a temperature of from about 700° C. to about 900° C. and ranges therebetween, for a duration of from about 1 minute to about 10 minutes and ranges therebetween. According to an exemplary embodiment, the anneal is performed with a ramp rate of from about 25° C./second (s) to about 50° C./s and ranges therebetween. Notably, in addition to O₂, the process can also have hydrogen (H₂) gas. For instance, in one exemplary embodiment, from about 5 percent (%) to about 15% H₂ is mixed with O₂ to form the (i.e., pure SiOx) bottom air-containing spacer 1102.

An interlayer dielectric (ILD) 1202 is then deposited over the gate stacks (i.e., gate dielectric 1002 and workfunction-setting metal(s) 1004) and fins 106. See FIG. 12. Suitable materials for ILD 1202 include, but are not limited to, oxide materials such as SiOx and/or organosilicate glass (SiCOH) and/or ultralow-κ interlayer dielectric (ULK-ILD) materials, e.g., having a dielectric constant κ of less than 2.7. Suitable ultralow-κ dielectric materials include, but are not limited to, porous organosilicate glass (pSiCOH). A process such as CVD, ALD, or PVD can be used to deposit the ILD 1202. Following deposition, the ILD 1202 can be polished down to the encapsulation liner 1006 using a process such as chemical mechanical polishing (CMP).

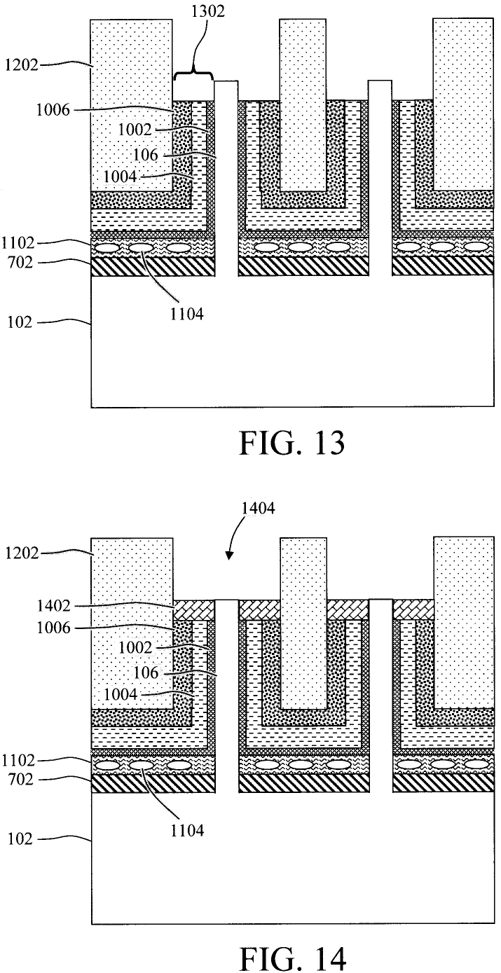

The encapsulation liner 1006 is now exposed at the tops of the fins 106. Exposure of the encapsulation liner 1006 enables its removal, as well as the underlying fin hardmasks 104 and gate stacks from the top of the fins 106. See FIG. 13. As shown in FIG. 13, the encapsulation liner 1006, the workfunction-setting metal(s) 1004, the gate dielectric 1002, and the fin hardmasks 104 have been removed from the top of the fins 106. The fins 106 will serve as vertical fin channels of the VFET device.

According to an exemplary embodiment, the encapsulation liner 1006, the workfunction-setting metal(s) 1004 and the gate dielectric 1002 are recessed such that a top surface of the encapsulation liner 1006, the workfunction-setting metal(s) 1004 and the gate dielectric 1002 is present below a top surface of the fins 106 (i.e., vertical fin channels). Doing so creates gaps 1302 between the sidewall at the tops of the fins 106 and the ILD 1202. See FIG. 13. As will be described in detail below, a top spacer will be formed in these gaps, and top source/drain regions will be formed on the exposed tops of the fins 106. The bottom spacer 902 and the top spacer will serve to offset the bottom source/drain regions 702 and the top source/drain regions from the gate stack, respectively. A directional (i.e., anisotropic) etching process such as RIE and/or a non-directional (i.e., isotropic) etching process such as a wet chemical etch or a gas phase etch can be employed to remove the encapsulation liner 1006, the workfunction-setting metal(s) 1004, the gate dielectric 1002, and the fin hardmasks 104 from the top of the fins 106.

A top spacer 1402 is then formed above the gate stack in the gaps 1302 alongside the tops of the fins 106 (i.e., vertical fin channels). See FIG. 14. Suitable materials for the top spacer 1402 include, but are not limited to, oxide spacer materials such as SiOx and/or silicon oxycarbide (SiOC) and/or nitride spacer materials such as SiN, silicon-boron-nitride (SiBN), siliconborocarbonitride (SiBCN) and/or silicon oxycarbonitride (SiOCN), which can be deposited into the gaps 1302 using a process such as CVD, ALD or PVD. Following deposition, an etch-back of the spacer material (e.g., using an oxide- or nitride-selective RIE as the case may be) is used to form the top spacer 1402 in the gaps 1302. Based on this process, according to an exemplary embodiment, a top surface of the top spacer 1402 is coplanar with the top surface of the fins 106. See FIG. 14. Further, this leaves a top surface of the fins 106 exposed alongside the top spacer 1402 which will enable the formation of the top source/drain regions.

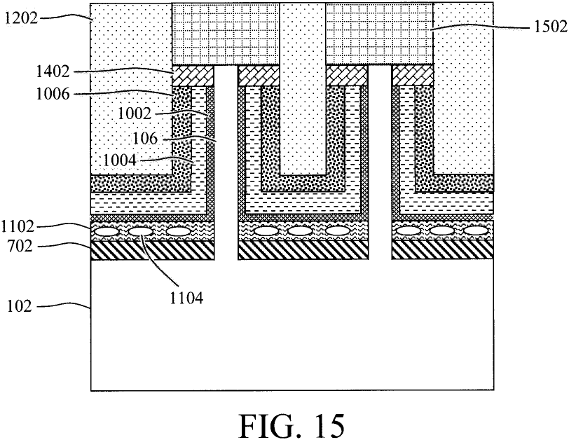

Namely, the above-described process of removing the encapsulation liner 1006, the workfunction-setting metal(s) 1004, the gate dielectric 1002, and the fin hardmasks 104 from the top of the fins 106, followed by the formation of the top spacer 1402 alongside the tops of the fins 106 creates trenches 1404 over the fins 106. As shown in FIG. 14, the tops of the fins 106 are exposed at the bottom of the trenches 1404. Top source/drain regions 1502 are then formed in the trenches 1404 at the tops of the fins 106 (i.e., vertical fin channels). See FIG. 15.

According to an exemplary embodiment, top source/drain regions 1502 are formed from an in-situ doped (i.e., during growth) or ex-situ doped (e.g., via ion implantation) epitaxial material such as epitaxial Si, epitaxial SiGe, etc. grown at the tops of the fins 106 and doped with an n-type or p-type dopant. As provided above, suitable n-type dopants include, but are not limited to, P and/or As. Suitable p-type dopants include, but are not limited to, B. Following growth, the epitaxial material can be planarized using a process such as CMP. As a result, the top surface of the top source/drain regions 1502 is coplanar with a top surface of the ILD 1202. See FIG. 15.

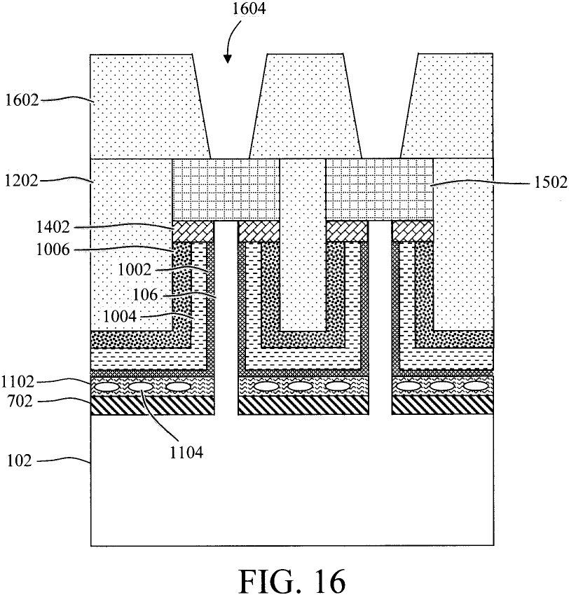

Contacts are next formed to the top source/drain regions 1502. To do so, an ILD 1602 is first deposited onto the ILD 1202 over the fins 106 (i.e., vertical fin channels). For clarity, the terms ‘first’ and ‘second’ may also be used herein when referring to the ILD 1202 and the ILD 1602. Suitable materials for ILD 1602 include, but are not limited to, oxide materials such as SiOx and/or SiCOH and/or ULK-ILD materials such as pSiCOH. A process such as CVD, ALD, or PVD can be used to deposit the ILD 1602. Following deposition, the ILD 1602 can be polished using a process such as CMP. Standard lithography and etching techniques (see above) are then employed to pattern contact trenches 1604 in the ILD 1602. As shown in FIG. 16, one of the contact trenches 1604 is present in the ILD 1602 over each of the top source/drain regions 1502.

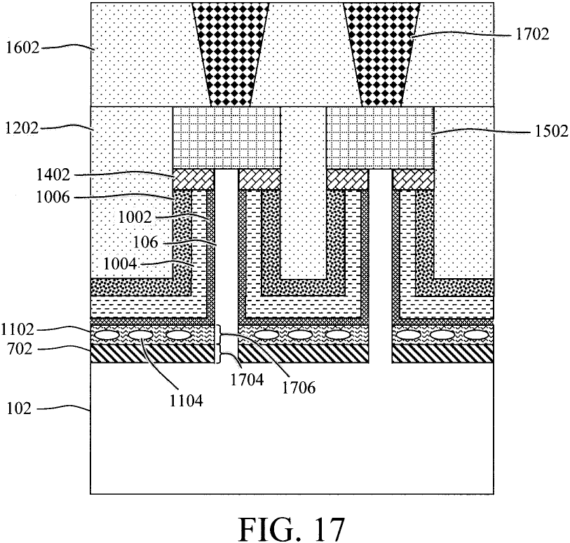

The contact trenches 1604 are then filled with a metal or a combination of metals to form contacts 1702 to the top source/drain regions 1502. See FIG. 17. Suitable metals include, but are not limited to, copper (Cu), tungsten (W), ruthenium (Ru), cobalt (Co), nickel (Ni) and/or platinum (Pt). The metal(s) can be deposited into the contact trenches 1604 using a process such as evaporation, sputtering, or electrochemical plating. Following deposition, the metal overburden can be removed using a process such as CMP. Prior to depositing the metal(s), a barrier layer (not shown) can be deposited into and lining the contact trenches 1604. Use of such a barrier layer helps to prevent diffusion of the metal(s) into the surrounding ILD 1602. Suitable barrier layer materials include, but are not limited to, ruthenium (Ru), tantalum (Ta), tantalum nitride (TaN), titanium (Ti) and/or titanium nitride (TiN). Additionally, a seed layer (not shown) can be deposited into and lining the contact trenches 1604 prior to metal deposition, i.e., in order to facilitate plating of the metal into the contact trenches 1604.

As shown in FIG. 17, there are some unique structural features of the present VFET device to be noted. For instance, based on the above-described bilayer spacer (i.e., first sidewall spacer 108/second sidewall spacer 402) design and process sequence, the bottom source/drain regions 702 are present at the base of the fins 106 alongside (and in direct contact with) a first portion 1704 of the sidewall of the fins 106. The bottom air-containing spacer 1102 is present directly on the bottom source/drain regions 702 alongside (and in direct contact with) a second portion 1706 of the sidewall of the fins 106 which is above the first portion 1704 of the sidewall.

With the above-described process the high Ge content SiGe bottom spacer 902 is placed prior to the gate stack (i.e., the gate dielectric 1002 and workfunction-setting metal(s) 1004). However, the (thermal) oxidation to form the bottom air-containing spacer 1102 occurs after formation of the gate stack. This process may result in some re-oxidation of the gate dielectric 1002 which can generate defects in the material and thereby degrade device performance. In order to avoid re-oxidation of the gate dielectric 1002, an alternative process flow is contemplated herein where both the placement of the high Ge content SiGe bottom spacer 902 and the (thermal) oxidation to form the bottom air spacer occur before the gate stack is formed, thereby avoiding altogether any exposure of the gate dielectric 1002 to re-oxidation.

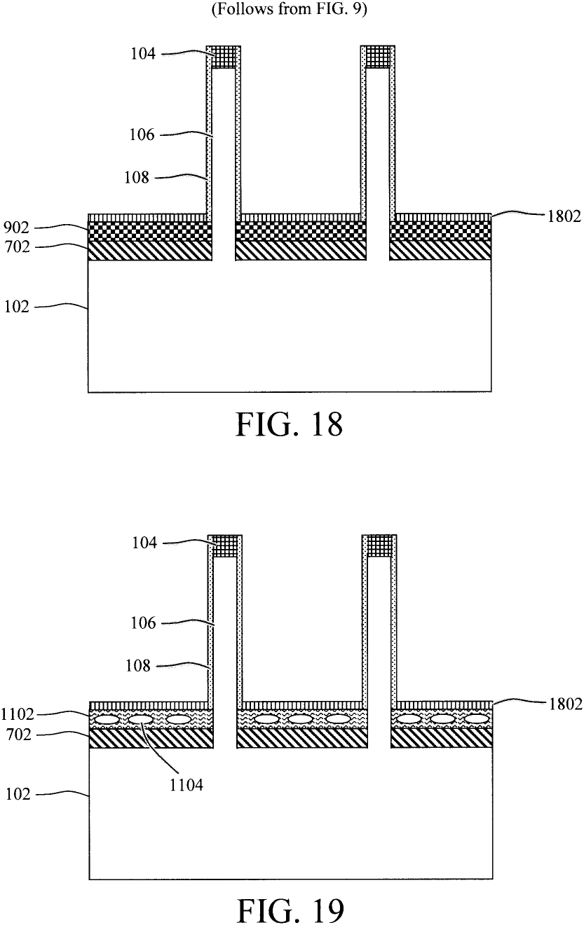

This alternative exemplary embodiment is now described by way of reference to FIGS. 18-21. The process begins in exactly the same manner as the example described in conjunction with the description of FIGS. 1-9 above, i.e., with the patterning of fins 106 in the substrate 102 using fin hardmasks 104, the formation of the bilayer spacer (i.e., first sidewall spacer 108/second sidewall spacer 402) along with the associated recess and trimming at the base of the fins 106 in exactly the same manner as described above, formation of the bottom source/drain regions 702 at the base of the fins 106, removal of the second sidewall spacer 402, and formation of the bottom spacer 902. As provided above, the bottom spacer 902 is formed from high Ge content SiGe, i.e., SiGe having from about 50% Ge to about 100% Ge (i.e., pure Ge) and ranges therebetween, such as SiGe having greater than or equal to about 60% Ge, SiGe having greater than or equal to about 75% Ge, or even SiGe having greater than or equal to about 80% Ge. Thus, what is depicted in FIG. 18 follows from the structure of FIG. 9.

In this case, however, a capping layer 1802 is next formed on the high Ge content SiGe bottom spacer 902. See FIG. 18. Suitable materials for the capping layer 1802 include, but are not limited to, nitride materials such as SiN, SiON and/or SiCN. According to an exemplary embodiment, the capping layer 1802 is formed using a directional deposition process whereby a greater amount of the capping layer material is deposited on horizontal surfaces (including on top of the bottom spacer 902) as compared to vertical surfaces (such as along sidewalls of the fins 106/first sidewall spacer 108). Thus, when an etch is used on the capping layer material, the timing of the etch needed to remove the capping layer material from the vertical surfaces will leave the capping layer 1802 shown in FIG. 18 on bottom spacer 902 since a greater amount of the capping layer material was deposited on the bottom spacer 902. By way of example only, a high-density plasma (HDP) chemical vapor deposition (CVD) or physical vapor deposition (PVD) process can be used for directional film deposition, and a nitride-selective isotropic etch can be used to remove the (thinner) capping layer material deposited onto the vertical surfaces. According to an exemplary embodiment, the capping layer 1802 is formed have a thickness of greater than about 1 nm.

The oxidation of the high Ge content SiGe bottom spacer 902 is then carried out in the same manner as described above, except with the capping layer 1802 rather than the gate stack being present over the bottom spacer 902, to form the bottom air-containing spacer 1102 between the bottom source/drain regions 702 and the capping layer 1802. Namely, according to an exemplary embodiment, the bottom spacer 902 is oxidized using a thermal oxidation process whereby the VFET device structure is annealed in an O₂-containing ambient under conditions (e.g., temperature, duration, etc.) sufficient to form the bottom air-containing spacer 1102 (i.e., pure SiOx) having air-containing pores 1104 distributed throughout. See FIG. 19. In one exemplary embodiment, the annealing is performed at a temperature of greater than about 700° C., for example, at a temperature of from about 700° C. to about 900° C. and ranges therebetween, for a duration of from about 1 minute to about 10 minutes and ranges therebetween. According to an exemplary embodiment, the anneal is performed with a ramp rate of from about 25° C./s to about 50° C./s and ranges therebetween. Notably, in addition to O₂, the process can also have H₂ gas. For instance, in one exemplary embodiment, from about 5% to about 15% H₂ is mixed with O₂ to form the (i.e., pure SiOx) bottom air-containing spacer 1102. As described above, the presence of the air-containing pores 1104 in the bottom air-containing spacer 1102 helps to greatly reduce the parasitic capacitance between the gate stacks and the bottom source/drain regions 702. The presence of the gate stack or, in this case, the capping layer 1802 helps promote formation of the (i.e., pure SiOx) bottom air-containing spacer 1102 during this oxidation process for example by providing a surface on which the SiOx being formed can adhere to.

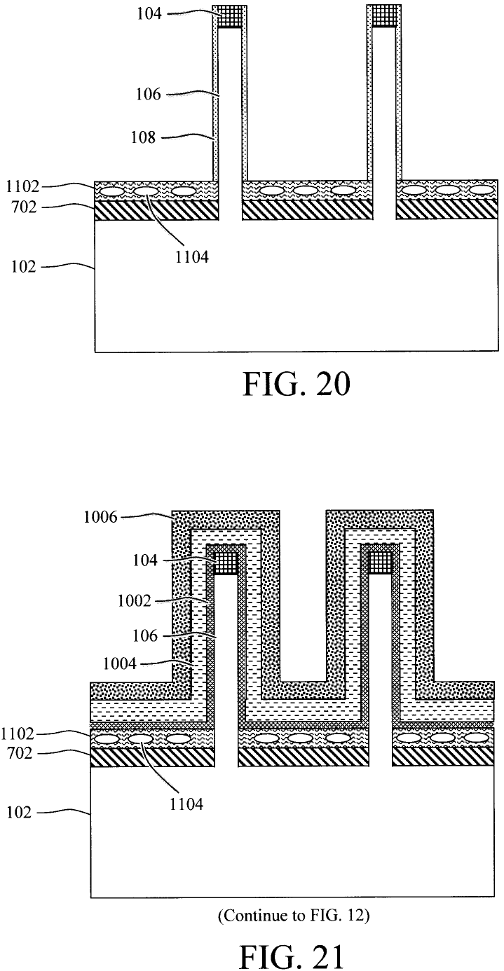

Following oxidation, the capping layer 1802 is then selectively removed. See FIG. 20. As provided above, the capping layer 1802 can be formed from a nitride material (e.g., SiN, SiON and/or SiCN). In that case, a nitride-selective etch such as a nitride-selective RIE can be employed to remove the capping layer 1802.

The first sidewall spacer 108 is also selectively removed as described above and the gate stacks are then formed alongside the fins 106 and over the bottom source/drain regions 702 and bottom air-containing spacer 1102. See FIG. 21. In the same manner as described above, the gate stacks include a gate dielectric 1002 disposed on the fins 106 and at least one workfunction-setting metal 1004 disposed on the gate dielectric 1002. Although not explicitly shown in the figures, an interfacial oxide may be formed on the exposed surfaces of the fins 106 prior to the gate dielectric 1002 such that the gate dielectric 1002 is disposed on the fins 106 over the interfacial oxide. Suitable materials, dimensions and fabrication techniques for the gate dielectric 1002, the workfunction-setting metal(s) 1004 and the interfacial oxide have been provided above.

The encapsulation liner 1006 is then formed on the gate stacks (i.e., gate dielectric 1002 and workfunction-setting metal(s) 1004) over the fins 106. As described above, the encapsulation liner 1006 will serve to protect the gate stacks during subsequent processing steps. Suitable materials, dimensions and fabrication techniques for the encapsulation liner 1006 have been provided above.

The remainder of the process is the same as that described in conjunction with the description of FIGS. 12-17 above. Namely, the (first) ILD 1202 is deposited over the gate stacks, the encapsulation liner 1006, the workfunction-setting metal(s) 1004, the gate dielectric 1002, and the fin hardmasks 104 are removed from the top of the fins 106, the top spacer 1402 are formed alongside the tops of the fins 106 (i.e., vertical fin channels), the top source/drain regions 1502 are formed at the tops of the fins 106, the (second) ILD 1602 is deposited onto the ILD 1202 over the fins 106, and the contacts 1702 are formed in the ILD 1602 to the top source/drain regions 1502. Thus, according to an alternative embodiment, what is depicted in FIG. 12 can also follow from the structure of FIG. 21.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A vertical field effect transistor (VFET) device, comprising:
at least one fin present on a substrate, wherein the at least one fin serves as a vertical fin channel of the VFET device;
a bottom source/drain region at a base of the at least one fin;
a bottom air-containing spacer disposed on the bottom source/drain region;
a gate stack alongside the at least one fin;
a top spacer above the gate stack at a top of the at least one fin; and
a top source/drain region at a top of the at least one fin.

2. The VFET device of claim 1, wherein air-containing pores are distributed throughout the bottom air-containing spacer.

3. The VFET device of claim 1, wherein the bottom air-containing spacer comprises pure silicon oxide (SiOx).

4. The VFET device of claim 1, further comprising:
an encapsulation liner disposed on the gate stack.

5. The VFET device of claim 4, wherein the encapsulation liner comprises a material selected from the group consisting of: silicon nitride (SiN), silicon carbide nitride (SiCN), amorphous silicon, and combinations thereof.

6. The VFET device of claim 1, wherein a top surface of the top spacer is coplanar with a top surface of the at least one fin.

7. The VFET device of claim 1, wherein the gate stack comprises:
a gate dielectric disposed on the at least one fin; and
at least one workfunction-setting metal disposed on the gate dielectric.

8. The VFET device of claim 1, further comprising:
at least one contact to the top source/drain region.

9. A vertical field effect transistor (VFET) device, comprising:
at least one fin present on a substrate, wherein the at least one fin serves as a vertical fin channel of the VFET device;
a bottom source/drain region at a base of the at least one fin, wherein the bottom source/drain region is in direct contact with a first portion of a sidewall of the at least one fin;
a bottom air-containing spacer disposed directly on the bottom source/drain region, wherein the bottom air-containing spacer is in direct contact with a second portion of the sidewall of the at least one fin;
a gate stack alongside the at least one fin;
a top spacer above the gate stack at a top of the at least one fin; and
a top source/drain region at a top of the at least one fin.

10. The VFET device of claim 9, wherein air-containing pores are distributed throughout the bottom air-containing spacer.

11. The VFET device of claim 9, wherein a top surface of the top spacer is coplanar with a top surface of the at least one fin.

12. The VFET device of claim 9, wherein the bottom spacer comprises pure SiOx.

13. The VFET device of claim 9, further comprising:
an encapsulation liner disposed on the gate stack, wherein the encapsulation liner comprises a material selected from the group consisting of: SiN, SiCN, amorphous silicon, and combinations thereof.

14. The VFET device of claim 9, wherein the bottom source/drain region comprises from about 0% germanium (Ge) to about 50% Ge.

15. A method of forming a vertical field effect transistor (VFET) device, the method comprising:
patterning at least one fin in a substrate;
forming a bottom source/drain region at a base of the at least one fin;
forming a bottom air spacer on the bottom source/drain region using oxidation, wherein the bottom air spacer comprises air-containing pores distributed throughout the bottom spacer;
forming a gate stack alongside the at least one fin, wherein the at least one fin serves as a vertical fin channel of the VFET device;
forming a top spacer above the gate stack at a top of the at least one fin; and
forming a top source/drain region at a top of the at least one fin.

16. The method of claim 15, further comprising:
forming a bottom spacer on the bottom source/drain region, wherein the bottom spacer comprises silicon germanium (SiGe) with a greater germanium (Ge) content than the bottom source/drain region; and
annealing the bottom spacer in an oxygen ambient to form the bottom air spacer on the bottom source/drain region.

17. The method of claim 16, wherein the bottom spacer comprises SiGe having from about 50% germanium (Ge) to about 100% Ge.

18. The method of claim 16, wherein the annealing is performed after the gate stack has been formed alongside the at least one fin.

19. The method of claim 16, further comprising:
forming a capping layer on the bottom spacer;
annealing the bottom spacer in the oxygen ambient to form the bottom air spacer on the bottom source/drain region;
removing the capping layer; and
forming the gate stack alongside the at least one fin.

20. The method of claim 16, further comprising:
forming a bilayer spacer alongside the at least one fin, wherein the bilayer spacer comprises a first sidewall spacer disposed on a sidewall of the at least one fin and a second sidewall spacer covering the first sidewall spacer, and wherein the second sidewall spacer is in direct contact with the at least one fin below the first sidewall spacer;
forming the bottom source/drain region at the base of the at least one fin beneath the bilayer spacer;
selectively removing the second sidewall spacer;
forming the bottom spacer on the bottom source/drain region at the base of the at least one fin beneath the first sidewall spacer; and
selectively removing the first sidewall spacer.
